(19) United States
(12) Patent Application Publication
(10) Pub. No.: US 2015/0071021 A1
(43) Pub. Date: Mar. 12, 2015

(54) ACCESSING INDEPENDENTLY ADDRESSABLE MEMORY CHIPS

(71) Applicant: Oracle International Corporation, Redwood City, CA (US)

(72) Inventors: Philip Amberg, San Jose, CA (US); Alex Chow, Palo Alto, CA (US); Robert David Hopkins, II, Foster City, CA (US)

(73) Assignee: Oracle International Corporation, Redwood City, CA (US)

(21) Appl. No.: 14/024,201

(22) Filed: Sep. 11, 2013

(51) Int. Cl. G11C 11/4063

(52) U.S. Cl. CPC G11C 11/4063
USPC 365/231

(57) ABSTRACT

A method of accessing rows and columns stored in a memory system that include memory chips that can be individually addressed and accessed is described. In order to leverage this capability, prior to performing a row-write request on the memory system, a computer system may transform the rows and the columns in a matrix. In particular, in response to receiving a row-write request to write to a row N in the matrix, the computer system rotates the row right by N elements, and writes the row in parallel to address N of the memory chips in the memory system. Similarly, in response to receiving a column-write request to write to column M in the matrix, the computer system rotates the column right by M elements, and writes the column in parallel to the memory chips in the memory system.

### BACKGROUND

1. Field

The present disclosure generally relates to techniques for accessing data in a memory system. More specifically, the present disclosure relates to techniques for accessing data in a memory system that includes independently addressable memory chips.

2. Related Art

In a typical commodity memory system, multiple dynamic-random-access-memory (DRAM) devices are arranged in parallel to provide a fixed-width data interface to a memory controller or a processor. Because of limited pin and routing resources in memory modules, DRAM devices within a given rank are usually accessed in lockstep, using the same address provided on a shared bus. However, this memory-access technique prevents individual addressing of each memory chip in the memory modules, which can reduce the efficiency of memory operations.

Hence, what is needed is a memory-access technique without the problems described above.

### SUMMARY

One embodiment of the present disclosure provides a computer system for accessing rows and columns in a matrix that is stored in a memory system, which includes a set of independently addressable memory chips. During operation, the computer system receives a row-write request to write to a row N in the matrix. In response to the row-write request, the computer system rotates the row right by N elements, and writes the row in parallel to address N of the memory chips in the memory system. Then, the computer system receives a column-write request to write to column M in the matrix. In response to the column-write request, the computer system rotates the column right by M elements, and writes the column in parallel to the memory chips in the memory system. Note that, during the write operation, a memory chip C in the memory system is assigned address (M+C) mod the number of rows in the matrix.

In some embodiments, the computer system receives a row-read request to read from row N in the matrix. In response to the row-read request, the computer system reads the row in parallel from address N of the memory chips in the memory system, and rotates the row returned by the parallel read operation left by N elements. Moreover, the computer system may receive a column-read request to read column M from the matrix. In response to the column-read request, the computer system may read the column in parallel from the memory chips in the memory system (where, during the read operation, the memory chip C in the memory system is assigned address (M+C) mod the number of rows in the matrix), and may rotates the column returned by the parallel read operation left by M elements.

Note that the rotating and writing operations may facilitate simultaneously accessing the elements of row N from the memory chips, and the rotating and writing operations may facilitate simultaneously accessing elements of column M from the memory chips.

Moreover, the memory chips may facilitate a configurable width for a memory operation.

Furthermore, the memory chips may be included in a ramp-stack chip package and/or a plank-stack chip package.

Additionally, frames of data stored in the memory chips may include corresponding error-correction information, where a frame has a pre-defined length and a pre-defined width, and the error-correction information facilitates identification and correction of errors in a given frame.

In some embodiments, the computer system writes data associated with a graph to the memory chips so that nodes in the graph are randomly distributed over the memory chips. Moreover, the computer system may accesses independent pages in the data concurrently on the memory chips.

Another embodiment provides a method that includes at least some of the operations performed by the computer system.

Another embodiment provides a computer-program product for use with the computer system. This computer-program product includes instructions for at least some of the operations performed by the computer system.

Another embodiment provides an integrated circuit (such as a processor or a memory controller) that performs at least some of the operations performed by the computer system.

Another embodiment provides a computer system or a memory system that includes the integrated circuit.

### BRIEF DESCRIPTION OF THE FIGURES

FIG. 1 is a block diagram illustrating a memory system with individually addressable memory chips in accordance with an embodiment of the present disclosure.

FIG. 2 is a drawing illustrating a row-major layout of a matrix in the memory system of FIG. 1 in accordance with an embodiment of the present disclosure.

FIG. 3 is a drawing illustrating row access in a rearranged matrix in the memory system of FIG. 1 that is optimized for row and column access in accordance with an embodiment of the present disclosure.

FIG. 4 is a drawing illustrating column access in a rearranged matrix in the memory system of FIG. 1 that is optimized for row and column access in accordance with an embodiment of the present disclosure.

FIG. 5 is a flow diagram illustrating a method for accessing rows and columns in a matrix that is stored in the memory system of FIG. 1 accordance with an embodiment of the present disclosure.

FIG. 6 is a flow diagram illustrating a method for storing data in the memory system of FIG. 1 accordance with an embodiment of the present disclosure.

FIG. 7 is a drawing illustrating a graph structure in accordance with an embodiment of the present disclosure.

FIG. 8 is a drawing illustrating a graph structure in accordance with an embodiment of the present disclosure.

FIG. 9 is a drawing illustrating a layout of the graph structure of FIG. 8 in the memory system of FIG. 1 in accordance with an embodiment of the present disclosure.

FIG. 10 is a flow diagram illustrating a method for storing data in the memory system of FIG. 1 in accordance with an embodiment of the present disclosure.

FIG. 11 is a block diagram illustrating a computer system in accordance with an embodiment of the present disclosure.

Table 1 provides pseudocode for rotating elements in a matrix in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

Embodiments of a computer system, a computer-program product, an integrated circuit (such as a processor or a memory controller), a system that includes the integrated circuit, and methods for accessing rows and columns in a memory system are described. This memory system includes memory chips that can be individually addressed and accessed (for example, the memory chips may be included in a ramp-stack chip package and/or a plank-stack chip package). In order to leverage this capability, prior to performing a row-write request on the memory system, the computer system may transform the rows and the columns in a matrix. In particular, in response to receiving a row-write request to write to a row N in the matrix, the computer system rotates the row right by N elements, and writes the row in parallel to address N of the memory chips in the memory system. Similarly, in response to receiving a column-write request to write to column M in the matrix, the computer system rotates the column right by M elements, and writes the column in parallel to the memory chips in the memory system. Note that, during the write operation, a memory chip C in the memory system is assigned address (M+C) mod the number of rows in the matrix.

This memory access technique may allow the data in elements in a given row or a given column in the matrix to be spread across different memory chips. In addition, the data may be mapped so that a given page is randomly distributed over the memory chips. In these ways, the memory chips can be independently and simultaneously accessed, which may facilitate a configurable width for the row-write operation and/or the column-write operation. Furthermore, because of this capability, the computer system may store frames of data in the memory chips with corresponding error-correction information so that errors in the frame can be identified and corrected. These memory-access and storage techniques may allow the memory system to be used efficiently and/or may facilitate new memory operations.

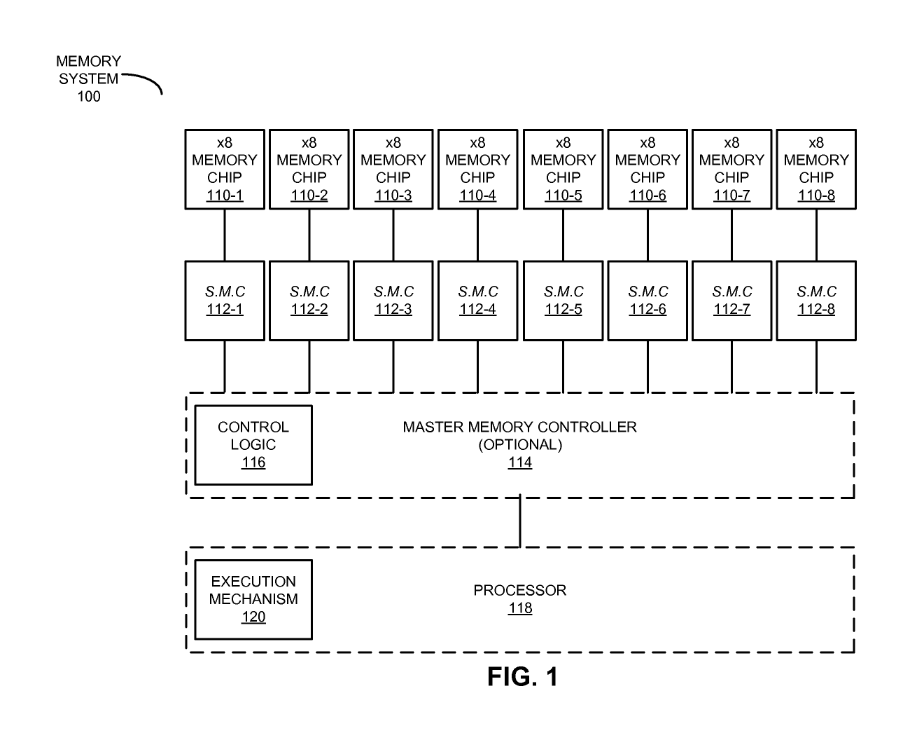

We now describe embodiments of the memory system and the memory-access and storage techniques. FIG. 1 presents a block diagram illustrating a memory system 100 with individually addressable (and accessible) memory chips 110. For example, memory chips 110 may include stacked semiconductor dies that are either perpendicular to or at an acute angle (between 0 and 90°) to a substrate (which is sometimes referred to as a ‘stacked memory’). Each of these memory chips may be controlled by an individual slave memory controller (S.M.C.) 112 that delivers address and control signals.

Activities of slave memory controllers 112 may be coordinated by an optional master memory controller 114 (which is sometimes referred to as an ‘integrated circuit’ in the discussion that follows). In particular, control logic 116 in optional master memory controller 114 may coordinate the activities of slave memory controllers 112 based on the desired access mode. Optional master memory controller 114 may also aggregate data returned from memory chips 110 on read operations and may distribute data to be written to memory chips 110 on write operations.

Alternatively or additionally, activities of slave memory controllers 112 may be coordinated and data to and from memory chips 110 may be aggregated, at least in part, by processor 118 (which is also sometimes referred to as the ‘integrated circuit’ in the discussion that follows). In particular, execution mechanism 120 in processor 118 may execute instructions associated with memory operations. In some embodiments, slave memory controllers 112 can be operated independently of optional master memory controller 114, which either may not be included in memory system 100 or may operate as a passthrough.

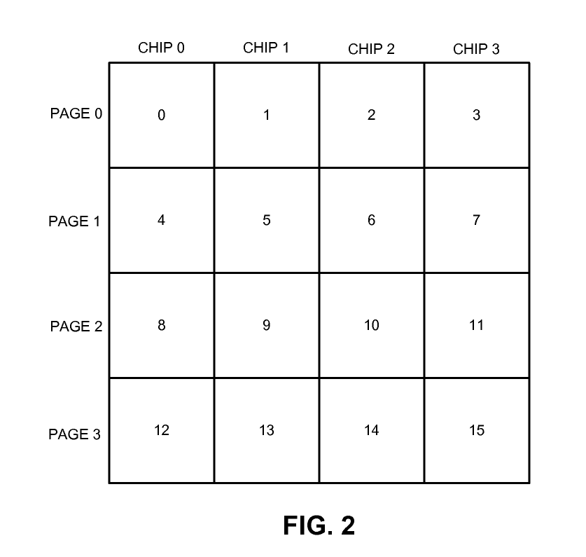

The memory operations, such as those in the memory-access and the storage techniques described below with reference to FIGS. 2-10, in memory system 100 may be implemented in hardware and/or software (for example, the memory operations may be performed by one or more integrated circuits). In the discussion that follows, the memory-access and the storage techniques are illustrated as being implemented using software that is executed by a processor (such as processor 118). While not shown in FIG. 1, processor 118 may be coupled to cache and/or mass memory.

As noted previously, memory system 100 may facilitate new memory operation, such as row/column matrix access. In general, applications such as matrix multiplication or database reads may benefit from the ability to efficiently read either a row or a column from a matrix (or a table). Because of address limitations, in a traditional memory system data can typically be organized to optimize for either row or column access. In contrast, in a stacked memory system, such as memory system 100, with individually addressable memory chips 110, data can be organized such that rows and columns can both be efficiently accessed.

As an illustration, consider storage of a matrix. FIG. 2 presents a drawing illustrating a row-major layout of a matrix in a memory system that is optimized for row accesses. In order to read a row (e.g., [0,1,2,3]), the same page on all the memory chips may be read. This access is efficient and all the data that is read is used. However, in order to read a column (e.g., [0,4,8,12]), each page may be opened and read in turn, with all the data being read to return just the four desired elements, a 25% read efficiency.

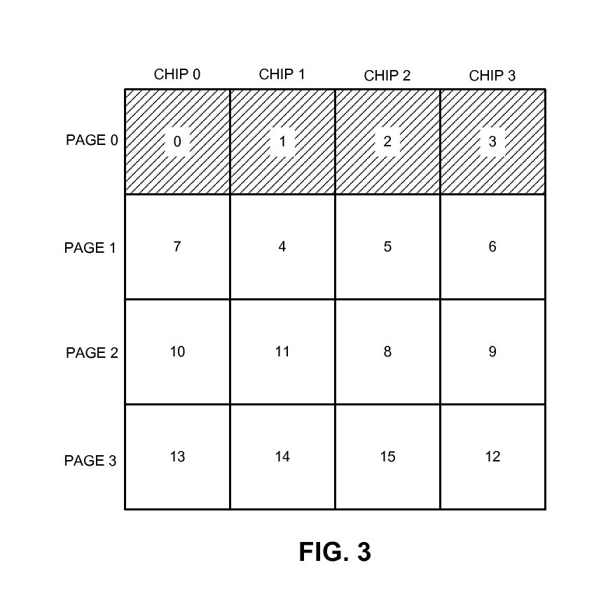

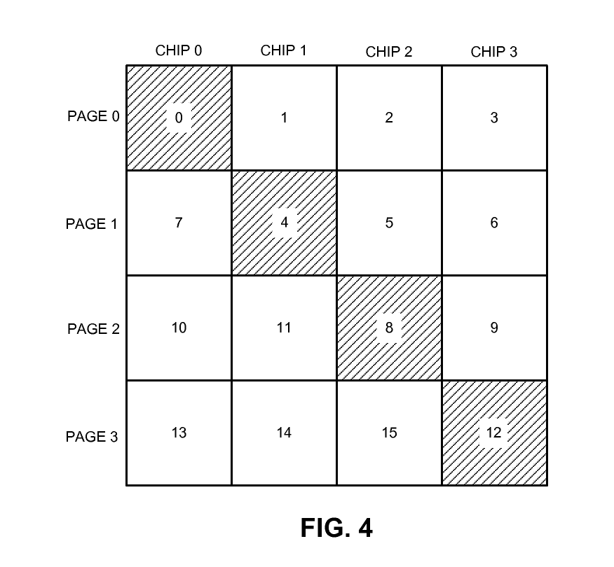

In an alternative approach, the software executed by processor 118 (FIG. 1) may apply a transform to the matrix so that the physical layout on memory chips 110 (FIG. 1) facilitates independent and simultaneous access to multiple memory chips (and, thus, to elements along the rows and/or the columns in the matrix). This is shown in FIG. 3, which presents a drawing illustrating row access in a rearranged matrix in memory system that is optimized for row and column access. In this case, in order to read a row (e.g., [0,1,2,3], which is illustrated by the dashed lines), the following addresses may be provided to the memory chips: chip0:page0, chip1:page0, chip2:page0, and chip3:page0. Similarly, as shown in FIG. 4, which presents a drawing illustrating column access in a rearranged matrix in memory system that is optimized for row and column access, in order to read a column (e.g., [0,4,8,12], which is illustrated by the dashed lines), the following addresses may be provided to the memory chips: chip0:page0, chip1:page1, chip2:page2, and chip3:page3. Note that the data elements in FIGS. 3 and 4 are arranged in such a way that the elements of any single row or column in the matrix are spread out to distinct memory chips. This property enables the independent and simultaneous (i.e., the parallel) access pattern (i.e., memory chips 110 in FIG. 1 may be independently addressable).

Pseudocode illustrating rotating of the rows and columns of the matrix prior to performing a row or column-write request (or a row or column-read request) on memory chips 110 (FIG. 1) in memory system 100 (FIG. 1) is shown in Table 1. Using this transformation technique, writing row N to the memory system may involve taking the input row data, rotating it right by N elements, and writing it to address N on all of memory chips 110 (FIG. 1). Similarly, reading row N may involve reading address N from all of memory chips 110 (FIG. 1) and rotating the returned data left by N elements to return the original row vector.

TABLE 1

for (row = 0; row < numRows; row++){
matrix[row] = rotate_right(matrix[row], row);
}

Moreover, reading column M from the memory system may require processor 118 (FIG. 1) to assign addresses for each of memory chips 110 (FIG. 1). For example, memory chip C may receive the address (M+C) mod (the number of rows in the matrix). Then, the data may be read from each of memory chips 110 (FIG. 1) at these corresponding addresses. Furthermore, the returned data may be rotated left M elements to return it in row-sorted order. Writing column M to the memory system may follow a similar process. In particular, the input column data may be rotated right M elements so that memory chip C receives the address (M+C) mod (the number of rows in the matrix). Then, the data may be written to each of memory chips 110 (FIG. 1) at these corresponding addresses.

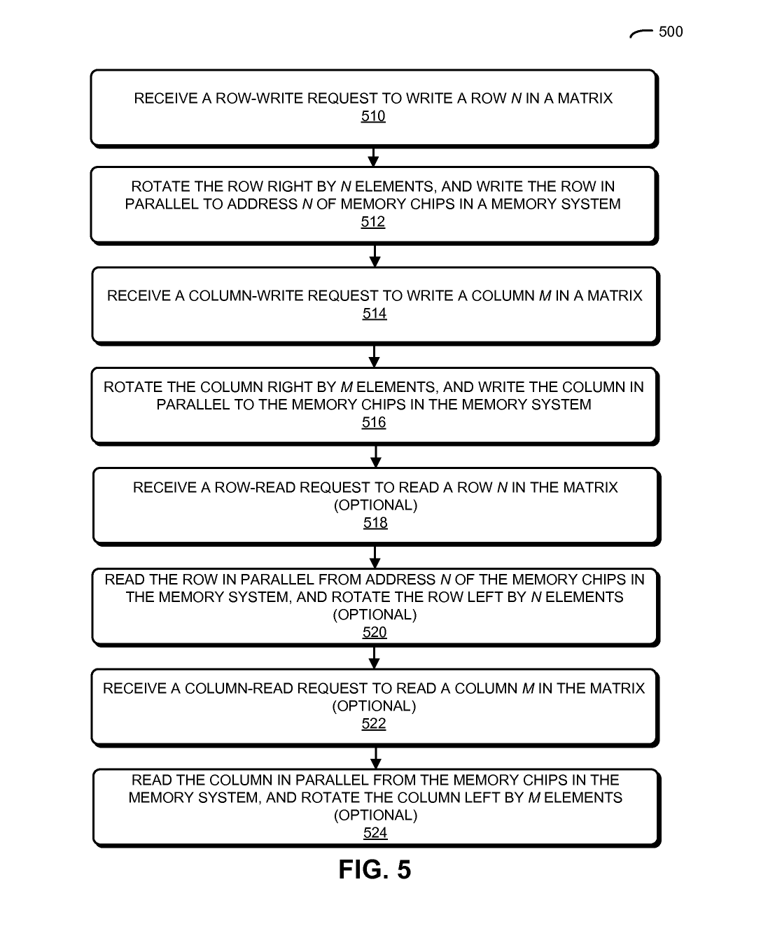

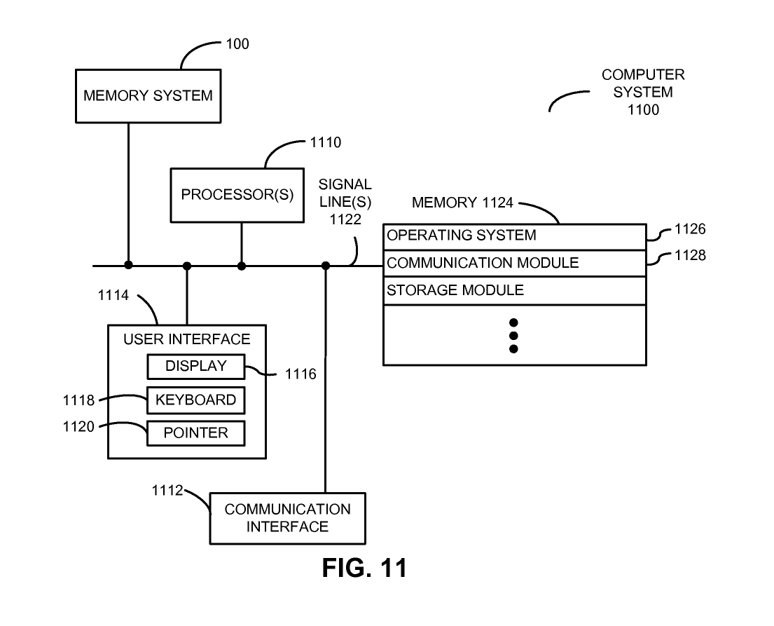

FIG. 5 presents a flow diagram illustrating a method 500 for accessing rows and columns in a matrix that is stored in memory system 100 (FIG. 1), which may be performed by a computer system (such as computer system 1100 in FIG. 11). During operation, the computer system receives a row-write request to write to a row N in the matrix (operation 510). In response to the row-write request, the computer system rotates the row right by N elements, and writes the row in parallel to address N of the memory chips in the memory system (operation 512). Then, the computer system receives a column-write request to write to column M in the matrix (operation 514). In response to the column-write request, the computer system rotates the column right by M elements, and writes the column in parallel to the memory chips in the memory system (operation 516). Note that, during the write operation, a memory chip C in the memory system is assigned address (M+C) mod the number of rows in the matrix.

In some embodiments, the computer system optionally receives a row-read request to read from row N in the matrix (operation 518). In response to the row-read request, the computer system optionally reads the row in parallel from address N of the memory chips in the memory system, and optionally rotates the row returned by the parallel read operation left by N elements (operation 520). Moreover, the computer system may optionally receive a column-read request to read column M from the matrix (operation 522). In response to the column-read request, the computer system may optionally read the column in parallel from the memory chips in the memory system (where, during the read operation, the memory chip C in the memory system is assigned address (M+C) mod the number of rows in the matrix), and may optionally rotates the column returned by the parallel read operation left by M elements (operation 524).

Note that the rotating and writing operations may facilitate simultaneously accessing the elements of row N from the memory chips, and the rotating and writing operations may facilitate simultaneously accessing elements of column M from the memory chips.

Moreover, the memory chips may facilitate a configurable width for a memory operation.

Furthermore, the memory chips may be included in a ramp-stack chip package and/or a plank-stack chip package.

The ability to independently and simultaneously access data on different memory chips in the memory system also has consequences for error correcting codes (ECC). Many enterprise applications require the use of ECC to reduce the failure rate of software due to memory read errors. Typically, this is implemented with an extra chip on the memory data bus that holds error-correction information obtained by passing the data words through a single-error-correction double-error-detecting (SECDED) code generator. When data is read, it is passed through a SECDED decoder to check whether it matches the original ECC information. This technique works well for typical memory systems because the memory system is always accessed the same way. However, for a configurable-width, individually addressable memory system (such as that shown in FIG. 1), the ECC word may be constructed from a separate set of data.

One approach is to use an extra chip in the memory system to store ECC information for rows and columns for the two access modes. This approach may be sub-optimal, however, because there is redundant information stored in the ECC chip. In particular, any given element in the data may be represented in the ECC information for a row read and for a column read. This approach may also be challenging because any modification of the data requires that the ECC information for a row access and a column access be re-computed. Thus, if a row was read and modified, the corresponding column may also be read in order to re-compute the ECC information before being written back. Consequently, any write becomes a read-modify-write operation.

Another technique takes advantage of the inherent burst length of memory components. In DRAM, a read of a particular address usually results in an 8-cycle burst of data starting from that address. Moreover, a typical DRAM component is 8-bits wide (×8), so the burst results in a 64-bit (8-byte) transfer (which provides an illustration of a ‘frame’ having a pre-defined length and a pre-defined width). The last 8-bit word of the burst can be used as the ECC word. Because all transfers will have this minimum granularity, the ECC information can always be computed and checked, regardless of the access mode. However, note that the 8-bits used for ECC in this example is inefficient. 8 bits of ECC information is typically used with 64 bits of data, while in this case there are 56 bits of data with an 8-bit ECC word. Consequently, this frame size is an illustration of the storage technique and frame sizes with different lengths and widths (and, thus, different ECC overhead) may be used.

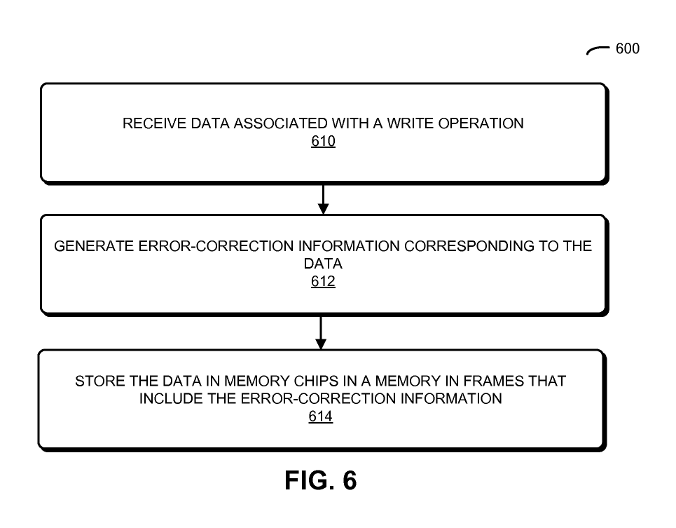

FIG. 6 presents a flow diagram illustrating a method 600 for storing data, which may be performed by a computer system (such as computer system 1100 in FIG. 11). During operation, the computer system receives data associated with a write operation (operation 610). Then, the computer system generates error-correction information corresponding to the data (operation 612). Next, the computer system stores the data in memory chips in a memory system in frames that include the error-correction information (operation 614), where the frames have a pre-defined length and a pre-defined width, the memory chips are independently addressable, and the error-correction information facilitates identification and correction of errors in a given frame.

Another use of independently addressable memory chips is for parallel graph traversal. Traversing graphs usually involves significant amounts of pointer-chasing, in which there are small reads from random memory locations. These reads are typically inefficient on traditional memory systems because the pointers being read generally fit within one page but eight pages may be opened across all eight memory chips, a 12.5% read efficiency. The configurable-width or individually addressable memory system shown in FIG. 1 can raise this efficiency to 100% because memory chips not being read from can be turned off, i.e., eight independent pages can be accessed simultaneously.

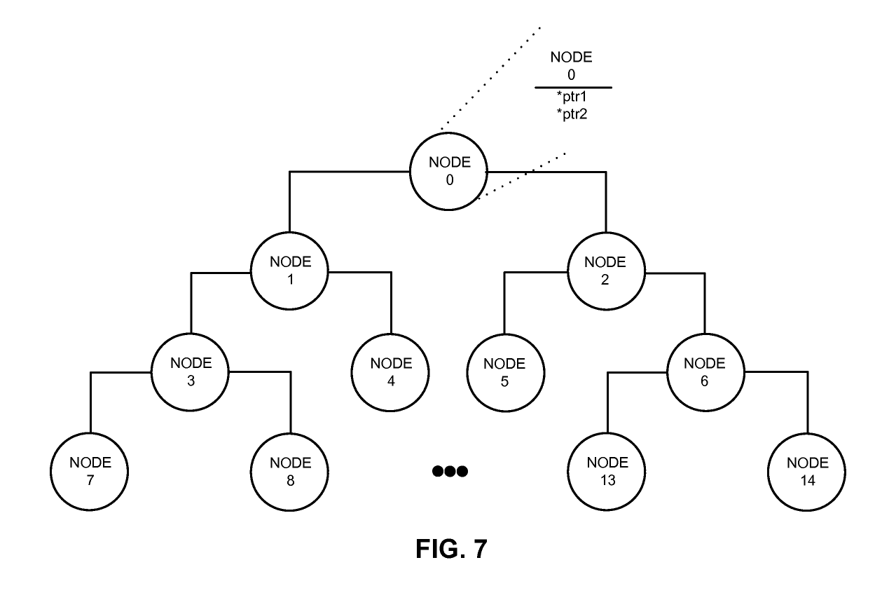

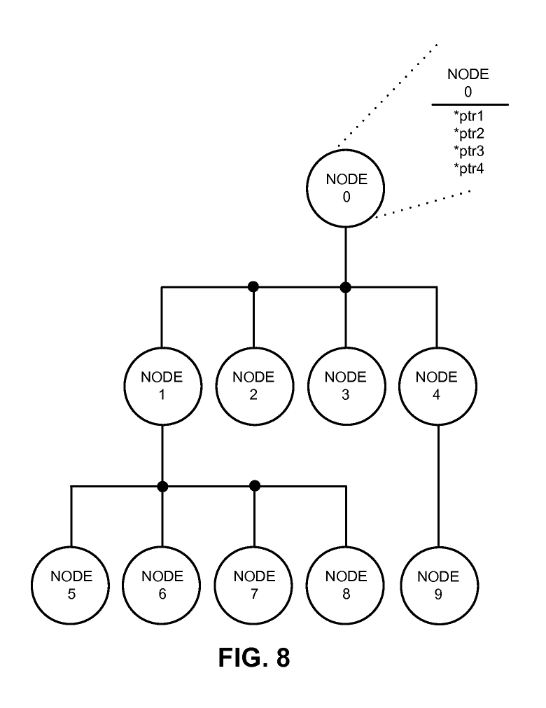

Consider the exemplary graphs in FIGS. 7 and 8. Each node in the graphs has a physical structure as shown to the right. In this example, the nodes only contain pointers to other nodes, but in other embodiments each node may have an additional pointer to point at payload data for each node.

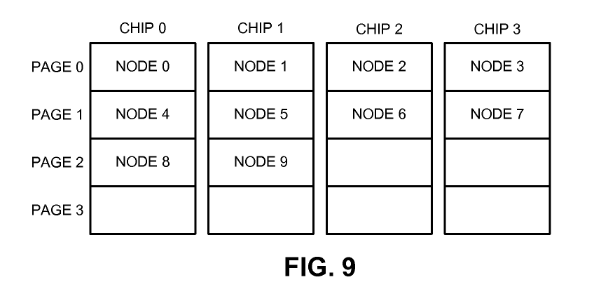

Because memory chips 110 (FIG. 1) can be simultaneously and independently accessed, the efficiency can be significantly improved if a large graph is randomly spread out in the memory system so that the probability of adjacent nodes being in the same page and/or the same memory chip is nearly zero. This is illustrated in FIG. 9, which presents a drawing illustrating a layout of the graph structure of FIG. 8 in memory. The graph traversal begins at the root of the tree, node 0. Pointers 1, 2, 3, and 4 may be read from node 0. Using these pointers, the computer system (i.e., processor 118 in FIG. 1, which executes software) can determine which memory chips contain the data. Next, the computer system sends pointer 1 to memory chip 1, pointer 2 to memory chip 2, pointer 3 to memory chip 3, and pointer 4 to memory chip 0. These four node accesses then occur simultaneously. Note that nodes 2 and 3 are leaves of the tree and do not return any subsequent pointers. Node 1 returns pointers 5, 6, 7, and 8, while node 4 returns pointer 9.

Because the parallelism in this storage technique is limited by the number of independent memory chips, the graph-traversal technique may choose which nodes to process first. In this example, the pointers from node 1 may be processed first. The computer system may feed pointer 5 to memory chip 1, pointer 6 to memory chip 2, pointer 7 to memory chip 3, and pointer 8 to memory chip 0. These nodes are all accessed simultaneously and it is determined that they are leaves and no additional processing is necessary. Next, the storage technique goes back to processing node 4 and sends pointer 9 to memory chip 1, returning the leaf node 9. Note that the page hit rate in this example is 100%, which means that every page opened in the memory system has data used from it. Thus, the individually addressable memory chips allow finer memory-access granularity, which makes applications that access small blocks of data more efficient.

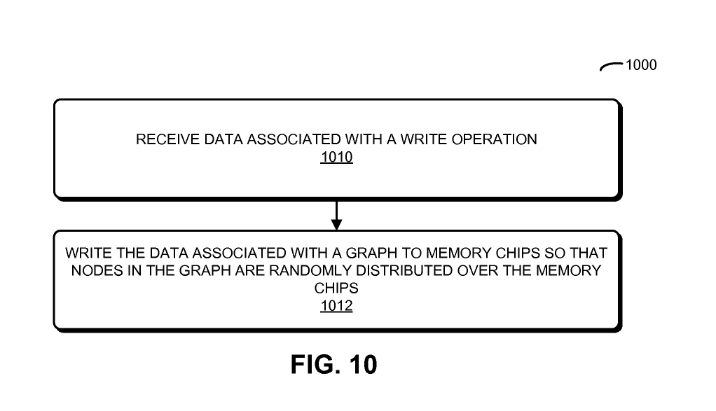

FIG. 10 presents a flow diagram illustrating a method 1000 for storing data, which may be performed by a computer system (such as computer system 1100 in FIG. 11). During operation, the computer system receives data associated with a write operation (operation 1010). Then, the computer system writes data associated with a graph to the memory chips so that nodes in the graph are randomly (or pseudorandomly) distributed over the memory chips (operation 1012). Moreover, the computer system accesses independent pages in the data concurrently on the memory chips (operation 1014).

In some embodiments of methods 500 (FIG. 5), 600 (FIGS. 6) and 1000 there may be additional or fewer operations. For example, instead of generating the error-correction information in operation 612 in FIG. 6, the computer system may access pre-existing error-correction information. Moreover, the order of the operations may be changed, and/or two or more operations may be combined into a single operation.

We now describe embodiments of the computer system. FIG. 11 presents a block diagram illustrating a computer system 600 that includes memory system 100, and which performs methods 500 (FIG. 5), 600 (FIG. 6) and/or 1000 (FIG. 10). Computer system 1100 includes one or more processing units or processors 1110, a communication interface 1112, a user interface 1114, and one or more signal lines 1122 coupling these components together. Note that the one or more processors 1110 may support parallel processing and/or multi-threaded operation, the communication interface 1112 may have a persistent communication connection, and the one or more signal lines 1122 may constitute a communication bus. Moreover, the user interface 1114 may include: a display 1116, a keyboard 1118, and/or a pointer 1120, such as a mouse.

Memory 1124 in computer system 1100 may include volatile memory and/or non-volatile memory. More specifically, memory 1124 may include: ROM, RAM, EPROM, EEPROM, flash memory, one or more smart cards, one or more magnetic disc storage devices, and/or one or more optical storage devices. Memory 1124 may store an operating system 1126 that includes procedures (or a set of instructions) for handling various basic system services for performing hardware-dependent tasks. Memory 1124 may also store procedures (or a set of instructions) in a communication module 1128. These communication procedures may be used for communicating with one or more computers and/or servers, including computers and/or servers that are remotely located with respect to computer system 1100.

Memory 1124 may also include multiple program modules (or sets of instructions), including: storage module 1130 (or a set of instructions). Note that one or more of these program modules (or sets of instructions) may constitute a computer-program mechanism.

During the accessing and/or the storage techniques, storage module 1130 may perform at least some of the operations in methods 500 (FIG. 5), 600 (FIG. 6) and/or 1000 (FIG. 10).

Instructions in the various modules in memory 1124 may be implemented in: a high-level procedural language, an object-oriented programming language, and/or in an assembly or machine language. Note that the programming language may be compiled or interpreted, e.g., configurable or configured, to be executed by the one or more processors 1110.

Although computer system 1100 is illustrated as having a number of discrete items, FIG. 11 is intended to be a functional description of the various features that may be present in computer system 1100 rather than a structural schematic of the embodiments described herein. In some embodiments, some or all of the functionality of computer system 1100 may be implemented in one or more application-specific integrated circuits (ASICs) and/or one or more digital signal processors (DSPs).

Components in computer system 1100 may be coupled by signal lines, links or buses. These connections may include electrical, optical, or electro-optical communication of signals and/or data. Furthermore, in the preceding embodiments, some components are shown directly connected to one another, while others are shown connected via intermediate components. In each instance, the method of interconnection, or ‘coupling,’ establishes some desired communication between two or more circuit nodes, or terminals. Such coupling may often be accomplished using a number of circuit configurations, as will be understood by those of skill in the art; for example, AC coupling and/or DC coupling may be used.

In some embodiments, functionality in these circuits, components and devices may be implemented in one or more: application-specific integrated circuits (ASICs), field-programmable gate arrays (FPGAs), and/or one or more digital signal processors (DSPs). Furthermore, functionality in the preceding embodiments may be implemented more in hardware and less in software, or less in hardware and more in software, as is known in the art. In general, the computer system may be at one location or may be distributed over multiple, geographically dispersed locations.

Note that computer system 1100 may include: a VLSI circuit, a switch, a hub, a bridge, a router, a communication system (such as a WDM communication system), a storage area network, a data center, a network (such as a local area network), and/or a computer system (such as a multiple-core processor computer system). Furthermore, the computer system may include, but is not limited to: a server (such as a multi-socket, multi-rack server), a laptop computer, a communication device or system, a personal computer, a work station, a mainframe computer, a blade, an enterprise computer, a data center, a tablet computer, a supercomputer, a network-attached-storage (NAS) system, a storage-area-network (SAN) system, a media player (such as an MP3 player), an appliance, a subnotebook/netbook, a smartphone, a cellular telephone, a network appliance, a set-top box, a personal digital assistant (PDA), a toy, a controller, a digital signal processor, a game console, a device controller, a computational engine within an appliance, a consumer-electronic device, a portable computing device or a portable electronic device, a personal organizer, and/or another electronic device.

Furthermore, the embodiments of the integrated circuit, the memory system and/or the computer system may include fewer components or additional components. Although these embodiments are illustrated as having a number of discrete items, the preceding embodiments are intended to be functional descriptions of the various features that may be present rather than structural schematics of the embodiments described herein. Consequently, in these embodiments two or more components may be combined into a single component, and/or a position of one or more components may be changed. In addition, functionality in the preceding embodiments of the integrated circuit, the memory system and/or the computer system may be implemented more in hardware and less in software, or less in hardware and more in software, as is known in the art.

An output of a process for designing an integrated circuit, or a portion of an integrated circuit, comprising one or more of the circuits described herein may be a computer-readable medium such as, for example, a magnetic tape or an optical or magnetic disk. The computer-readable medium may be encoded with data structures or other information describing circuitry that may be physically instantiated as an integrated circuit or portion of an integrated circuit. Although various formats may be used for such encoding, these data structures are commonly written in: Caltech Intermediate Format (CIF), Calma GDS II Stream Format (GDSII) or Electronic Design Interchange Format (EDIF). Those of skill in the art of integrated circuit design can develop such data structures from schematics of the type detailed above and the corresponding descriptions and encode the data structures on a computer-readable medium. Those of skill in the art of integrated circuit fabrication can use such encoded data to fabricate integrated circuits comprising one or more of the circuits described herein.

In the preceding description, we refer to ‘some embodiments.’ Note that ‘some embodiments’ describes a subset of all of the possible embodiments, but does not always specify the same subset of embodiments.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. A computer-implemented method for accessing rows and columns in a matrix that is stored in a memory system comprising a set of independently addressable memory chips, the method comprising:
using the computer, receiving a row-write request to write to a row N in the matrix;
in response to the row-write request, rotating the row right by N elements, and writing the row in parallel to address N of the memory chips in the memory system;
receiving a column-write request to write to column M in the matrix; and
in response to the column-write request, rotating the column right by M elements, and writing the column in parallel to the memory chips in the memory system, wherein, during the write operation, a memory chip C in the memory system is assigned address (M+C) mod the number of rows in the matrix.

2. The method of claim 1, wherein the method further comprises:
receiving a row-read request to read from row N in the matrix; and
in response to the row-read request, reading the row in parallel from address N of the memory chips in the memory system, and rotating the row returned by the parallel read operation left by N elements.

3. The method of claim 1, wherein the method further comprises:
receiving a column-read request to read column M from the matrix;
in response to the column-read request, reading the column in parallel from the memory chips in the memory system, wherein, during the read operation, the memory chip C in the memory system is assigned address (M+C) mod the number of rows in the matrix; and
rotating the column returned by the parallel read operation left by M elements.

4. The method of claim 1, wherein the rotating and writing operations facilitate simultaneously accessing the elements of row N from the memory chips; and
wherein the rotating and writing operations facilitate simultaneously accessing elements of column M from the memory chips.

5. The method of claim 1, wherein the memory chips facilitate a configurable width for a memory operation.

6. The method of claim 1, wherein the memory chips are included in one of: a ramp-stack chip package and a plank-stack chip package.

7. The method of claim 1, wherein frames of data stored in the memory chips include corresponding error-correction information;
wherein a frame has a pre-defined length and a pre-defined width; and
wherein the error-correction information facilitates identification and correction of errors in a given frame.

8. The method of claim 1, wherein the method further comprises writing data associated with a graph to the memory chips so that nodes in the graph are randomly distributed over the memory chips.

9. The method of claim 8, wherein the method further comprises accessing independent pages in the data concurrently on the memory chips.

10. A computer-program product for use in conjunction with a computer system, the computer-program product comprising a non-transitory computer-readable storage medium and a computer-program mechanism embedded therein, to access rows and columns in a matrix that is stored in a memory system comprising a set of independently addressable memory chips, the computer-program mechanism including:
instructions for receiving a row-write request to write to a row N in the matrix;
in response to the row-write request, instructions for rotating the row right by N elements, and instructions for writing the row in parallel to address N of the memory chips in the memory system;
instructions for receiving a column-write request to write to column M in the matrix; and
in response to the column-write request, instructions for rotating the column right by M elements, and instructions for writing the column in parallel to the memory chips in the memory system, wherein, during the write operation, a memory chip C in the memory system is assigned address (M+C) mod the number of rows in the matrix.

11. The computer-program product of claim 10, wherein the computer-program mechanism further includes:
instructions for receiving a row-read request to read from row N in the matrix; and
in response to the row-read request, instructions for reading the row in parallel from address N of the memory chips in the memory system, and instructions for rotating the row returned by the parallel read operation left by N elements.

12. The computer-program product of claim 10, wherein the computer-program mechanism further includes:
instructions for receiving a column-read request to read column M from the matrix;
in response to the column-read request, instructions for reading the column in parallel from the memory chips in the memory system, wherein, during the read operation, the memory chip C in the memory system is assigned address (M+C) mod the number of rows in the matrix; and
instructions for rotating the column returned by the parallel read operation left by M elements.

13. The computer-program product of claim 10, wherein the rotating and writing operations facilitate simultaneously accessing the elements of row N from the memory chips; and
wherein the rotating and writing operations facilitate simultaneously accessing elements of column M from the memory chips.

14. The computer-program product of claim 10, wherein the memory chips facilitate a configurable width for a memory operation.

15. The computer-program product of claim 10, wherein the memory chips are included in one of: a ramp-stack chip package and a plank-stack chip package.

16. The computer-program product of claim 10, wherein frames of data stored in the memory chips include corresponding error-correction information;
wherein a frame has a pre-defined length and a pre-defined width; and
wherein the error-correction information facilitates identification and correction of errors in a given frame.

17. The computer-program product of claim 10, wherein the computer-program mechanism further includes instructions for writing data associated with a graph to the memory chips so that nodes in the graph are randomly distributed over the memory chips.

18. The computer-program product of claim 10, wherein the computer-program mechanism further includes instructions for accessing independent pages in the data concurrently on the memory chips.

19. A computer system, comprising:
a processor;
memory;
a program module, wherein the program module is stored in the memory and configured to be executed by the processor to access rows and columns in a matrix that is stored in a memory system comprising a set of independently addressable memory chips, the program module including:
instructions for receiving a row-write request to write to a row N in the matrix;
in response to the row-write request, instructions for rotating the row right by N elements, and instructions for writing the row in parallel to address N of the memory chips in the memory system;
instructions for receiving a column-write request to write to column M in the matrix; and
in response to the column-write request, instructions for rotating the column right by M elements, and instructions for writing the column in parallel to the memory chips in the memory system, wherein, during the write operation, a memory chip C in the memory system is assigned address (M+C) mod the number of rows in the matrix.

20. The computer system of claim 19, wherein the program module further includes:
instructions for receiving a row-read request to read from row N in the matrix; and
in response to the row-read request, instructions for reading the row in parallel from address N of the memory chips in the memory system, and instructions for rotating the row returned by the parallel read operation left by N elements.
